(19) United States
(12) Patent Application Publication
(10) Pub. No.: US 2026/0136934 A1
(43) Pub. Date: May 14, 2026

(54) COOLING ASSEMBLY INCLUDING MECHANICAL REINFORCEMENT TO PREVENT WARPAGE

(71) Applicant: SEMICONDUCTOR COMPONENTS INDUSTRIES, LLC, Scottsdale, AZ (US)

(72) Inventor: Seungwon IM, Bucheon (KR)

(73) Assignee: SEMICONDUCTOR COMPONENTS INDUSTRIES, LLC, Scottsdale, AZ (US)

(21) Appl. No.: 19/381,897

(22) Filed: Nov. 6, 2025

Related U.S. Application Data
(60) Provisional application No. 63/719,354, filed on Nov. 12, 2024.

(51) Int. Cl. H01L 23/46; H01L 21/48; H01L 23/00

(52) U.S. Cl. CPC H10W 40/40; H10W 40/037; H10W 90/734

(57) ABSTRACT

A cooling assembly is provided for dissipating heat generated by a semiconductor device. The assembly includes a cooler having a housing and a top plate that define an internal fluid channel. The cooler incorporates at least one reinforcement structure disposed within it, the structure composed of a reinforcement material that is different than a material of the top plate or the housing. The reinforced architecture increases the structural rigidity of the cooler to mitigate warpage and the potential for die cracking or delamination.

### CROSS-REFERENCE TO RELATED APPLICATIONS

This application claims the benefit of U.S. Provisional Application No. 63/719,354, filed on November 12, 2024, which is hereby incorporated by reference in its entirety.

### TECHNICAL FIELD

This description relates to semiconductor package assemblies and, more particularly, to a cooling assembly including mechanical reinforcement to prevent warpage.

### BACKGROUND

Semiconductor package assemblies (e.g., semiconductor device power modules) may include substrates that are bonded to thermal dissipation mechanisms (e.g., heat sinks, water jackets, etc.). Mechanical stress due to thermal cycling can weaken the bond between the semiconductor package assemblies and the cooler, leading to poor cooling performance and even detachment.

### SUMMARY

In a general aspect, an apparatus includes a cooler. The cooler includes a housing and a top plate joined to the housing, with the top plate and the housing defining a fluid channel. The cooler also includes a fluid input port providing a fluid path into the fluid channel , and a fluid output port providing a fluid path out of the fluid channel. The apparatus further includes a reinforcement structure disposed within the cooler, the reinforcement structure composed of a reinforcement material that is different than a material of the top plate and the housing.

In some aspects, the reinforcement material is a ceramic. In some aspects, the reinforcement structure is embedded in the housing. In some aspects, where the reinforcement structure is embedded in the housing, the housing includes a groove in which the reinforcement structure is disposed. The housing also includes a seal disposed over the reinforcement structure within the groove and the sealing the fluid channel. In some aspects, the reinforcement structure is embedded in the top plate. In some aspects, where the reinforcement structure is embedded in the top plate, the top plate includes a base having a recessed area where the reinforcement structure is disposed and a cover disposed over the reinforcement structure.

In some aspects, the reinforcement structure is a first reinforcement structure embedded in the housing, and the apparatus includes a second reinforcement structure embedded in the top plate. In some aspects, the apparatus further comprises a semiconductor device bonded to the top plate. In some aspects, the semiconductor device includes a silicon carbide die.

In another general aspect, an apparatus includes a cooler having a reinforcement structure disposed within the cooler. The reinforcement structure is composed of a reinforcement material that is different than a material of the cooler. The apparatus also includes a power module bonded to the cooler. In some aspects, the power module is a first power module, and the apparatus includes a second power module and a third power module bonded to the cooler. In some aspects, each of the first power module, the second power module, and the third power module are configured to provide an output corresponding to a phase of a three-phase electrical output. In some aspects, the power module includes a first transistor die corresponding to a high side of a half bridge circuit and a second transistor die corresponding to a low side of the half bridge circuit.

In some aspects, the cooler includes an upper portion and a lower portion joined to the upper portion, with the upper portion and the lower portion defining a fluid channel. The reinforcement structure is embedded in at least one of the upper portion and the lower portion. In some aspects, the reinforcement structure is a first reinforcement structure embedded in the upper portion, and the apparatus includes a second reinforcement structure embedded in the lower portion. In some aspects, the reinforcement structure is composed of a ceramic material.

In another general aspect, a method includes disposing a reinforcement structure in at least one of a top plate and a housing of a cooler. The reinforcement structure is composed of a reinforcement material that is different than a material of at least one of the top plate and the housing. The method also includes joining the top plate to the housing to form a cooler, with the top plate and the housing defining a fluid channel. The cooler includes a fluid input port providing a fluid path into the fluid channel and a fluid output port providing a fluid path out of the fluid channel.

In some aspects of the method, disposing the reinforcement structure in at least one of a top plate and a housing includes embedding the reinforcement structure in the housing. In some aspects of the method, disposing the reinforcement structure in at least one of a top plate and a housing includes embedding the reinforcement structure in the top plate. In some aspects of the method, the reinforcement material is a ceramic and the material of at least one of the housing and the top plate is aluminum. In some aspects of the method, joining the top plate to the housing includes friction stir welding.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a top view of the top plate of a cooler.

FIG. 1B illustrates a bottom view of the top plate of FIG. 1A.

FIG. 1C illustrates a top view of a housing of a cooler.

FIG. 1D illustrates a bottom view the housing of FIG. 1C.

FIG. 1E illustrates a cooler assembled from the top plate of FIGS. 1A and 1B and the housing of FIGS. 1C and 1D.

FIG. 2A is a top view of the cooling assembly in accordance with at least one embodiment of the present disclosure.

FIG. 2B is a front sectional view of the cooling assembly of FIG. 2A.

FIG. 2C is a side sectional view of the cooling assembly of FIG. 2A.

FIGS. 3A-3J depict example geometries of a reinforcement structure for a top plate in accordance with at least one embodiment of the present disclosure.

FIGS. 4A-4J depict example geometries of a reinforcement structure for a top plate in accordance with at least one embodiment of the present disclosure.

FIGS. 5A-5C set forth an example process for fabricating a top plate of a cooler having an embedded reinforcement structure in accordance with at least one embodiment of the present disclosure.

FIGS. 6A-6C set forth an example process for fabricating a top plate of a cooler having an embedded reinforcement structure in accordance with at least one embodiment of the present disclosure.

FIGS. 7A-7B set forth an example process for fabricating a housing of a cooler having an embedded reinforcement structure in accordance with at least one embodiment of the present disclosure.

FIGS. 8A and 8B set forth an example process for fabricating a cooler using the housing assembly of FIG. 7B.

FIG. 9 sets forth a sectional view of another example cooling assembly in accordance with at least one embodiment of the present disclosure.

FIG. 10A is a front view of a power module in accordance with at least one embodiment of the present disclosure.

FIG. 10B is a rear view of the power module of FIG. 10A.

FIG. 10C is a perspective view of the power module of FIG. 10A.

FIG. 11 sets forth a sectional view of another example cooling assembly in accordance with at least one embodiment of the present disclosure.

FIG. 12 is a perspective view of an example cooling assembly in accordance with at least one embodiment of the present disclosure.

FIG. 13 is a perspective view of an example cooling assembly in accordance with at least one embodiment of the present disclosure.

FIG. 14 sets forth a flow chart of an example method of fabricating a cooler in accordance with at least one embodiment of the present disclosure.

In the various drawings, which are not necessarily drawn to scale, like reference symbols may indicate like and/or similar components (elements, structures, etc.) in different views and/or different implementations. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are repeated for context and ease of cross reference between related views. Also, not all like elements in the drawings may be specifically referenced with a reference symbol when multiple instances of an element are illustrated.

### DETAILED DESCRIPTION

A cooler is a thermal dissipation structure configured to remove heat from one or more attached semiconductor devices. The cooler includes a body defining an internal fluid channel through which a coolant (e.g., water, dielectric fluid, or refrigerant) flows between an inlet port and an outlet port. In some implementations, a cooler includes a housing and an attached top plate that define the fluid channel. The cooler can include internal fins, posts, turbulators, or other flow-disrupting structures disposed within the fluid channel to increase internal surface area and improve heat transfer. A mounting surface of the cooler provides a thermally conductive interface to a semiconductor package, power module, or other electronic assembly, enabling heat generated during operation to be efficiently transferred into the coolant. The cooler may be formed from thermally conductive materials such as copper, aluminum, or combinations thereof.

Semiconductor devices such as power modules or integrated circuit packages are coupled to the cooler to dissipate heat generated by those devices. For example, the semiconductor devices can be sintered directly to the cooler using a metal sinter layer (e.g., silver) or by soldering. During thermal cycling, differences in coefficient of thermal expansion between the cooler and the semiconductor package generate stress at the interface. If the cooler lacks sufficient rigidity, warpage causes the cooler surface and/or semiconductor device to deflect, inducing bending stresses into the bond joint (e.g., sinter or solder joint). Such deformation can create localized lifting or separation of the sinter layer, potentially generating micro-cracks, voids, or delamination, which increases thermal resistance and may ultimately cause device failure. Further, deformation of the semiconductor device can cause die cracking or delamination of the die from its substrate.

The rigidity of the cooler is defined as the cooler’s resistance to bending or out-of-plane deformation. As used herein, “rigidity” or “structural rigidity” refers to the ability of the cooler to resist mechanical deformation when bonded to a semiconductor package and subjected to external forces such as clamping pressure, internal fluid pressure, or thermally induced stresses during operation. A deficiency in rigidity can result in warpage. As used herein, “warpage” refers to a deviation in flatness of the cooler structure such that one or more portions bow, bend, twist, or otherwise deflect from an intended plane. Warpage may occur during manufacturing, assembly (e.g., when sintering or bonding semiconductor packages to the cooler), or during operation due to thermal effects.

Material selection affects rigidity and the corresponding susceptibility to warpage. For example, aluminum has a relatively low elastic modulus and is thus more likely to warp when exposed to high heat.

Accordingly, the present disclosure provides an improved thermal dissipation structure engineered for increased stiffness through the incorporation of a reinforcement structure strategically located within the cooler, such as in the top plate, the housing, or a combination of both. This reinforcement structure is configured to substantially increase the overall rigidity of the cooler, effectively mitigating warpage and maintaining the flatness of the mounting surface despite high clamping forces, internal fluid pressure variations, and severe thermal cycling stresses. This reinforced architecture ensures the mechanical integrity of the solder or sinter joint, enabling highly reliable heat transfer from the semiconductor devices.

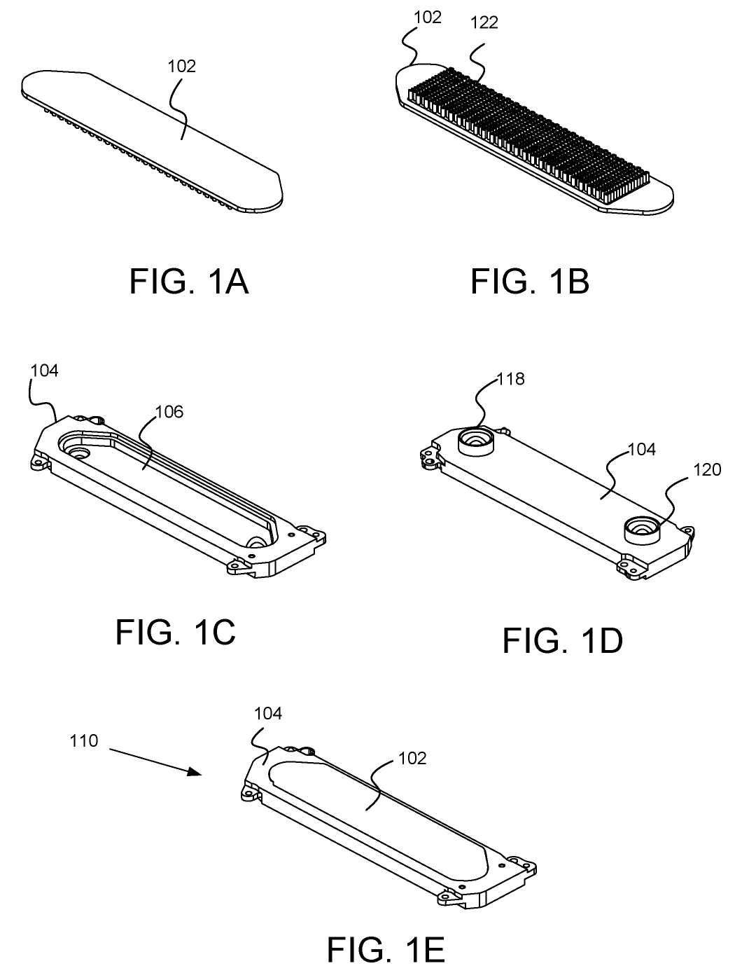

For further explanation, FIGS. 1A-1B illustrate a perspective view of example top plate 102 for an example cooler in accordance with at least one embodiment of the present disclosure. FIG. 1A illustrates a top view of the top plate showing its top surface. FIG. 1B illustrates a bottom view of the top plate 102 showing a fin array 122 extending from the bottom surface of the top plate 102. FIGS. 1C-1D illustrate a perspective view of an example housing 104 for an example cooler in accordance with at least one embodiment of the present disclosure. FIG. 1C illustrates a top view of the housing 104 including a recessed area 106. FIG. 1D illustrates a bottom view of the housing 104 including a fluid inlet port 118 and a fluid outlet port 120. The top plate 102 is joined to the housing 104 such that the bottom surface of the top plate 102 and the recessed area of the housing define a fluid channel coupled to the inlet port 118 and the outlet port. FIG. 1E illustrates a cooler 110 that is assembled from the top plate 102 and the housing 104 of FIGS. 1A-1D. One or more semiconductor devices can be attached to the top surface of the cooler, whereby cooling fluid circulating through the cooler removes heat from the semiconductor device(s). In various examples, the top plate 102 can be composed of aluminum, copper, nickel-clad copper, and so forth. In various examples, the housing 104 can be composed of aluminum or copper.

Although the term ‘top plate’ is referred to, and sometimes described as, a plate-like structure, it will be appreciated that embodiments of the present disclosure are not limited to such an implementation. Thus, a ‘top plate’ as used herein can refer to an upper housing of any shape and a ‘housing’ as used herein can refer to a lower housing, where the upper and lower housing are assembled to form a cooler.

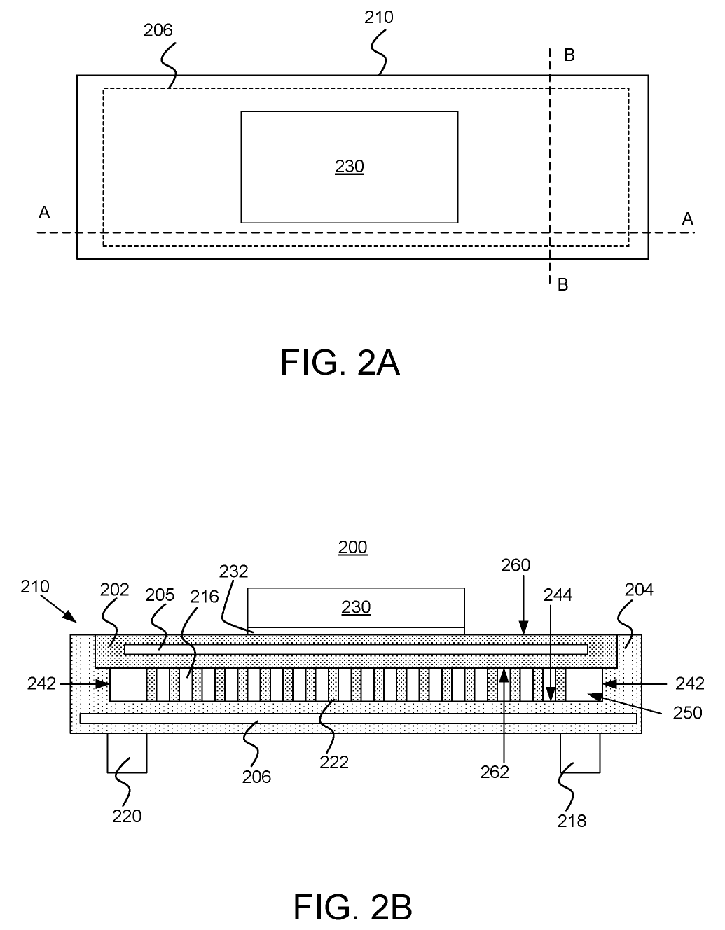

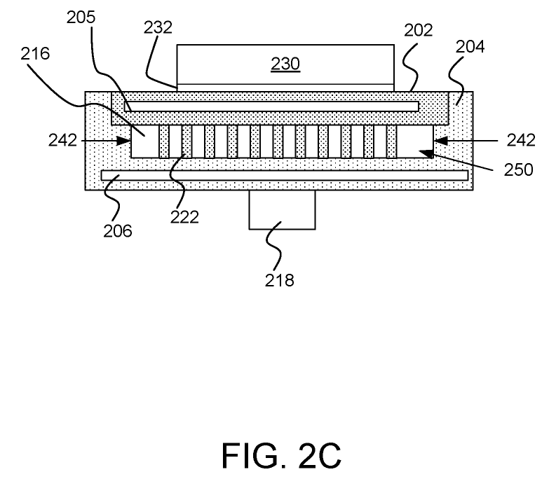

For further explanation, FIGS. 2A-2C illustrate an example cooling assembly 200 including a cooler 210 configured to remove heat from a semiconductor device 230 in accordance with at least one embodiment of the present disclosure. FIG. 2A is a top view of the cooling assembly 200, in which a semiconductor device is mounted on the cooler 210. FIG. 2A also depicts a reinforcement structure 206 embedded in the cooler 210. The reinforcement structure 206 is shown in dashed lines as it would be obscured in a top view of the assembly 200. In some examples, the reinforcement structure 206 is a different material than the body of the assembly (the top plate and/or the housing) and provides increased rigidity and/or a greater resistance to warpage during thermal cycling or mechanical strain compared to a cooler 210 that lacks the reinforcement structure 206. The reinforcement structure 206 and similar structures are discussed in detail below.

FIG. 2B is a sectional front view of the cooling assembly 200 taken along line A-A of FIG. 2A. FIG. 2C is a sectional side view of the cooling assembly 200 taken along line B-B of FIG. 2A. As depicted in FIGS. 2B and 2C, the cooler 210 includes a housing 204 and the top plate 202 that together define an internal fluid channel 216. The top plate 202 can include some or all of the features of the top plate depicted in FIGS. 1A-1B. The housing 204 can include some or all of the features of the housing 104 depicted in FIGS. 1C-1D. A fluid inlet port 218 and a fluid outlet port 220 are fluidly coupled to the fluid channel 216 such that a cooling medium enters the cooler 210 through the inlet port 218, passes through the fluid channel 216, and exits through the outlet port 220. The assembly 200 shown in FIGS. 2A-2C enables direct thermal transfer from the semiconductor device 230 into the cooler 210 and into the coolant flowing through the fluid channel 216. FIG. 2B also shows the reinforcement structure 206 disposed in the housing 204 and a reinforcement structure 205 disposed in the top plate 202. The reinforcement structures 205, 206 and similar structures are discussed in detail below.

In various implementations, the cooler 210 can be formed from thermally conductive materials such as copper, aluminum, or combinations thereof. In some implementations, both the top plate 202 and the housing 204 are constructed of aluminum (e.g., constructed only of aluminum). In other implementations, both the top plate 202 and the housing 204 are constructed of copper (e.g., constructed only of copper). In yet other implementations, the top plate 202 is copper and the housing 204 is aluminum, allowing copper to be located proximate to the semiconductor device to enhance thermal conduction while aluminum reduces overall mass and cost. In other implementations, the top plate 202 is aluminum and the housing 204 is copper, allowing structural rigidity and fin integration in the housing while reducing mass in the top plate. In yet other implementations, at least one of the top plate 202 and the housing 204 is a hybrid construction including both aluminum and copper components. For example, the top plate 202 can include an aluminum body and a copper or nickel-clad copper surface.

The top plate 202 includes a top surface 260 of the top plate 202 upon which the semiconductor device 230 is mounted, and a bottom surface 262 that is opposite the top surface 260. The housing 204 includes a recessed area 250 (also referred to as a cavity) that includes a wall 242 having a wall surface and a floor 244 having a floor surface of the recessed area. The top plates bottom surface 262, the wall surface, and the floor surface define, at least in part, the fluid channel 216. The fluid channel 216 can convey various types of coolant. In some examples, the coolant includes water or water-based solutions containing corrosion inhibitors. In other examples, the coolant is a dielectric fluid, allowing the cooler to operate in electrically sensitive environments such as high-voltage power modules. Suitable dielectric fluids include, for example, fluorinated fluids, silicone oils, or hydrocarbon-based dielectric coolants. In some examples, refrigerants may be used in phase-change cooling systems.

In some implementations, as shown in FIG. 2B, one or more fins 222 extend into the fluid channel 216 to increase the internal surface area exposed to coolant flow. In some examples, the fins are formed as part of the top plate 202 and extend into the fluid channel 216 from the bottom surface 262 of the top plate 202. In some examples of these implementations, the fins 222 contact the floor surface of the housing 204. In other examples of these implementations, the fins 222 do not contact the floor surface FS of the housing 204. In other implementations, the fins 222 are formed as part of the housing 204 and extend from the floor surface of the recessed area 250 of the housing 204 into the fluid channel 216. In some examples of these implementations, the fins 222 contact the bottom surface 262 of the top plate 202. In other examples of these implementations, the fins 222 do not contact the bottom surface 262 of the top plate 202.

The fins 222 may have various geometries, including but not limited to straight fins, pin fins, louvered fins, tapered fins, or curved fins configured to induce turbulence or directional flow. In some implementations, the fins 222 extend between the top plate 202 and the housing 204 to mechanically couple opposing walls of the fluid channel 216 and increase the structural rigidity of the cooler 210. Increasing fin height, thickness, or density may further increase rigidity and reduce warpage of the cooler 210.

In the example of FIG. 2B, the semiconductor device 230 is mounted on the top surface of the cooler 210, specifically, the top plate 202. The semiconductor device 230 can include a semiconductor package, a power module, a multi-die package, or a bare semiconductor die. In some implementations (as shown in FIG. 2B), a bond layer 232 is disposed between the semiconductor device 230 and the cooler 210 and provides both thermal conduction and mechanical attachment. The bond layer 232 may include solder, sintered metal (e.g., silver sinter paste), conductive adhesive, transient liquid phase bonding material, or other attachment materials. Additionally or alternatively, semiconductor device 230 can be mechanically fastened to the cooler 210 using screws, bolts, clamps, and the like.

In some implementations, the top plate 202 and housing 204 are joined using brazing, diffusion bonding, adhesive bonding, laser welding, or other suitable joining techniques. In a particular implementation, the top plate 202 and the housing 204 are joined together by friction stir welding. As used herein, friction stir welding (FSW) refers to a solid-state joining process in which a rotating tool is forced against and traversed along a seam between adjacent components. The heat generated by friction plastically deforms the material without melting it, producing a metallurgically bonded joint. FSW provides a low-porosity, high-strength interface and maintains the mechanical and thermal properties of the joined materials. Using friction stir welding to couple the top plate 202 and the housing 204 may be particularly advantageous when the cooler 210 is constructed from dissimilar metals, such as a copper top plate and an aluminum housing, or vice versa. In these implementations, FSW can create mechanical seal capable of withstanding internal coolant pressure while preserving thermal conduction across the interface. Additionally, the solid-state nature of the bonding process can minimize distortion and residual stresses that could otherwise contribute to warpage of the cooler 210.

In some implementations, the top plate 202 and the housing 204 are mechanically fastened together using screws, bolts, or other threaded fasteners. In such embodiments, one or more threaded holes may be formed in the top plate 202 and housing, and corresponding fasteners are inserted to apply a compressive clamping force along the interface. The mechanical fasteners may be used alone or in combination with other joining techniques, including friction stir welding, brazing, or adhesive bonding, to provide both mechanical strength and fluid sealing performance.

In some implementations, a seal (not shown) is disposed between the top plate 202 and the housing 204 to provide a coolant-tight interface around the fluid channel 216. In some examples, the housing 204 includes a recessed groove formed along at least a portion of its perimeter, and the seal is positioned within the groove prior to joining the components, and described in more detail below. In various implementations, the seal can include an O-ring, gasket, compressible polymer seal, elastomeric ring, or other sealing structure or dispensable sealing material configured to prevent coolant leakage when the top plate 202 is secured to the housing 204. During assembly, the seal is compressed between the top plate 202 and the housing 204 as the components are fastened or welded together.

As described above, insufficient rigidity of the cooler 210 can result in warpage when the cooler is subjected to mechanical loads or thermal cycling, leading to deformation of the mounting surface and degradation of the bond layer between the cooler and the semiconductor device. In the example of FIG. 2B, the reinforcement structures 205, 206 are provided to increase the rigidity of the cooler 210.

In some examples, rigidity is characterized by the elastic modulus E of the material. In some examples, rigidity can be characterized by the flexural rigidity of the structure. As used herein, “flexural rigidity” refers to the bending stiffness of a structure and may be expressed as the product of the elastic modulus 𝐸 of the material and the area moment of inertia 𝐼 of the structure’s cross-section. Warpage can be characterized by the peak-to-valley height difference measured across a surface of the cooler or by a curvature value. A structure that exhibits increased warpage under mechanical or thermal load is considered to have insufficient rigidity.

The reinforcement structures 205, 206 are an embedded feature designed to substantially increase the rigidity (resistance to bending and warpage) of the cooler 210 and attached semiconductor device 230. The reinforcement structures 205, 206 act to maintain the flatness of the mounting surface under operating conditions and manufacturing stresses, thereby ensuring the long-term reliability of the bond joint and semiconductor die(s) included in the semiconductor device. The reinforcement structures 205, 206 can adopt various geometries as described below, which may be selected based on the size and anticipated load profile of the cooler 210, but the purpose of each geometry is to increase the structural rigidity and mitigate against warpage. In some examples, the reinforcement structures 205, 206 are implemented by one or more flat longitudinal beams that are embedded in the cooler. For example, these beams can run parallel to the longer dimension of the cooler, providing focused reinforcement against bending in that critical direction. In other examples, the reinforcement structures 205, 206 are implemented by a ring or frame positioned along the entire perimeter of the cooler, thus providing uniform resistance to warpage and edge-lifting stresses. A smaller internal ring can also implement the reinforcement structures 205, 206, positioned strategically, for example, directly beneath the footprint of the semiconductor device(s) or within regions of anticipated maximum deflection. In other examples, the reinforcement structures 205, 206 can be implemented by an entire plate of increased thickness or a plate composed of a rigidity-enhancing material, such as the entire top plate or a reinforcing layer embedded the cooler housing. In various implementations, the reinforcement structures 205, 206 can differ in geometry. In various implementations, the reinforcement structures 205, 206 can differ in dimensions; for example, reinforcement structure 206 can be longer and/or wider than reinforcement structure 205. In a particular implementation, the reinforcement structure is wider than the distance between the inlet port 218 and the outlet port 220, such that the reinforcement structure 206 includes openings corresponding to the inlet port 218 and the outlet port 220. In some implementations, either the reinforcement structures 205 or the reinforcement structures 206 can be omitted.

The choice of material for the reinforcement structures 205, 206 is driven by the requirement for a high elastic modulus and compatibility with the cooler's material(s). As such, the reinforcement structure can be fabricated from, or entirely composed of, various structurally rigid materials. In some examples, the reinforcement structures 205, 206 include or are entirely composed of metal, but not limited to copper, steel (e.g., stainless steel), or high-strength metal alloys. In some examples, reinforcement structures 205, 206 include or are entirely composed of ceramic material such as aluminum nitride or silicon nitride or other high-modulus ceramic composites. In some examples, the reinforcement structures 205, 206 include or are entirely composed of polymers and plastics, including fiber-reinforced plastics, high-strength polymers, or polymer matrix composites with tailored stiffness properties. In some examples, the reinforcement structures 205, 206 include or are entirely composed of a metal matrix composite such as aluminum silicon carbide (AlSiC). In some examples, the reinforcement structures 205, 206 include or are entirely composed of a composite laminate such copper-clad molybdenum or copper-clad invar. In some examples, the reinforcement structures 205, 206 utilize a hybrid structure including two or more different technologies. In various implementations, the reinforcement structures 205, 206 can differ in material composition.

In some implementations, the reinforcement structure 205 is embedded in the top plate 202 by inserting the reinforcement structure 205 between two layers of the top plate 202. For example, the top plate 202 can include an upper cover and a lower fin structure, where the reinforcement structure 205 is inserted between the cover and the fin structure. In other examples, the reinforcement structure 205 is attached to an outer portion of the top plate 202. In various examples, the reinforcement structure 205 is attached to or within the top plate 202 via welding, including FSW, brazing, and the like.

In some implementations, the reinforcement structure 206 is embedded in the housing 204 by inserting the reinforcement structure 206 between two layers of the housing 204. For example, the housing can include an upper portion defining the fluid channel and a bottom cover (not shown) that includes the inlet and outlet ports, where the reinforcement structure 206 is inserted between the upper portion of the housing 204 and the bottom cover. In other examples, the reinforcement structure 205 is attached to the floor of the recessed area 106, 250 or is embedded in the floor of the recessed area 106, 250. In various examples, the reinforcement structure 206 is attached to or within the housing 204 via welding, including FSW, brazing, and the like.

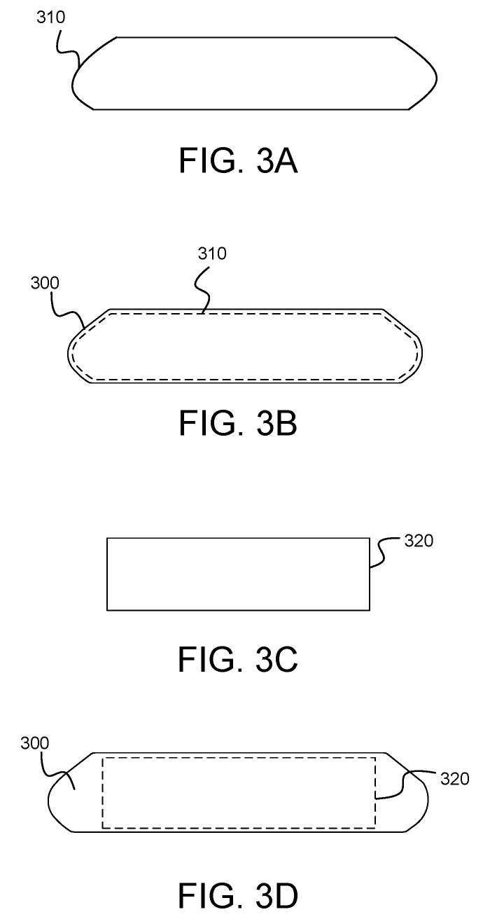

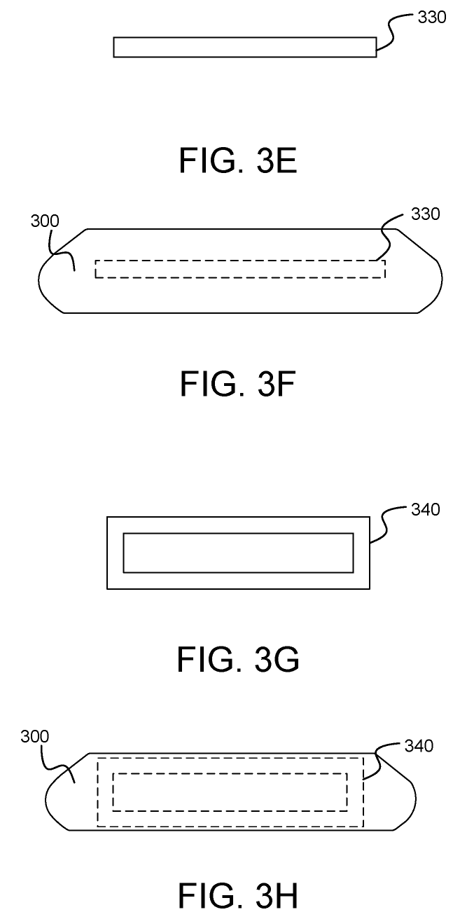

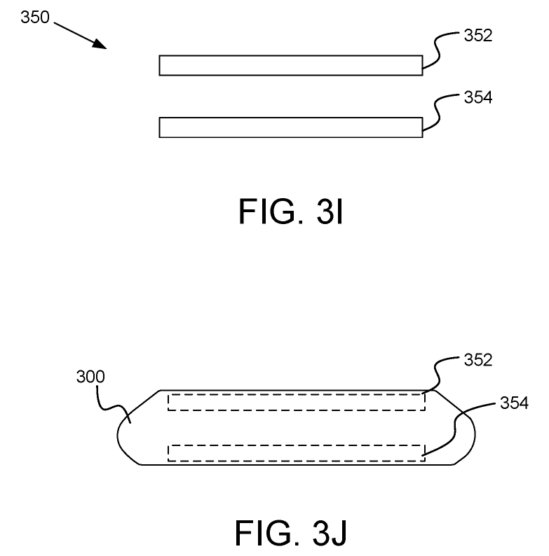

For further explanation FIGS. 3A-3J depict various geometries and installations of a reinforcement structure in a top plate 300 of a cooler in accordance various embodiments of the present disclosure. FIG. 3A depicts an example reinforcement structure 310 having a geometry that conforms to the shape of the top plate 300, and is therefore referred to as a complete geometry. In this example, the reinforcement structure 310 is the same shape and profile as the top plate 300 but on a slightly smaller scale. FIG. 3B illustrates a top view of the top plate 300 having the reinforcement structure 310 embedded within top plate 300, where dashed lines indicate that reinforcement structure 310 is obscured from view.

FIG. 3C depicts an example reinforcement structure 320 having a rectangular plate geometry that conforms to a rectangular subsection of the top plate 300. FIG. 3D illustrates a top view of the top plate 300 having the reinforcement structure 320 embedded within top plate 300, where dashed lines indicate that reinforcement structure 320 is obscured from view. Here, the reinforcement structure does not extend into the curved end portions of the top plate profile, and is therefore referred to as a partial geometry.

FIG. 3E depicts an example reinforcement structure 330 having a beam geometry. FIG. 3F illustrates a top view of the top plate 300 having the reinforcement structure 330 embedded within top plate 300, where dashed lines indicate that reinforcement structure 330 is obscured from view.

FIG. 3G depicts an example reinforcement structure 340 having a ring or frame geometry having an aperture in the interior portion of the reinforcement structure 340, and it thus referred to as a ring geometry. FIG. 3H illustrates a top view of the top plate 300 having the reinforcement structure 340 embedded within top plate 300, where dashed lines indicate that reinforcement structure 340 is obscured from view. In some examples, the shape of the ring can conform to the profile of the top plate 300.

FIG. 3I depicts an example reinforcement structure 350 having two or more beam portions 352, 354, and it thus referred to as a split geometry. FIG. 3J illustrates a top view of the top plate 300 having the reinforcement structure 350 embedded within top plate 300, where dashed lines indicate that reinforcement structure 350 is obscured from view.

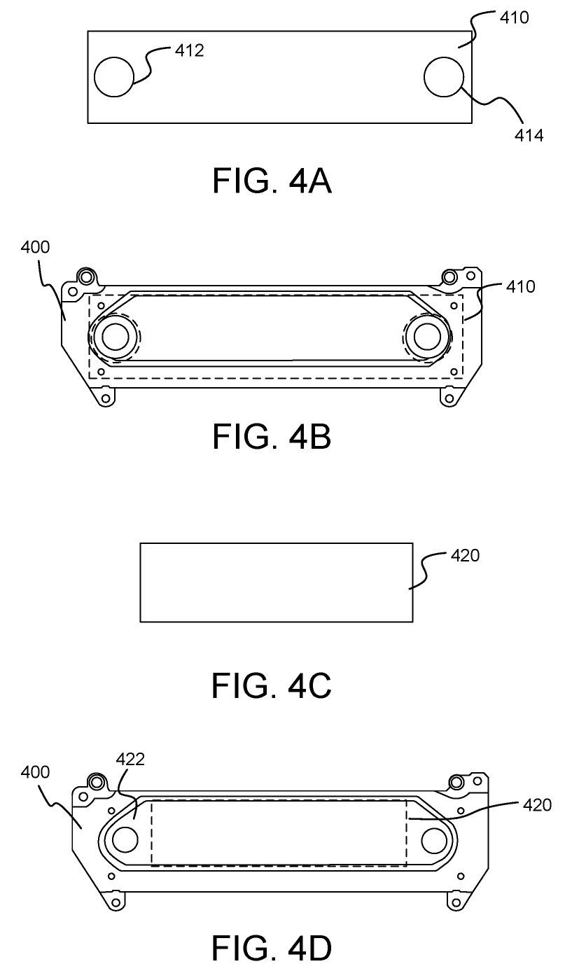

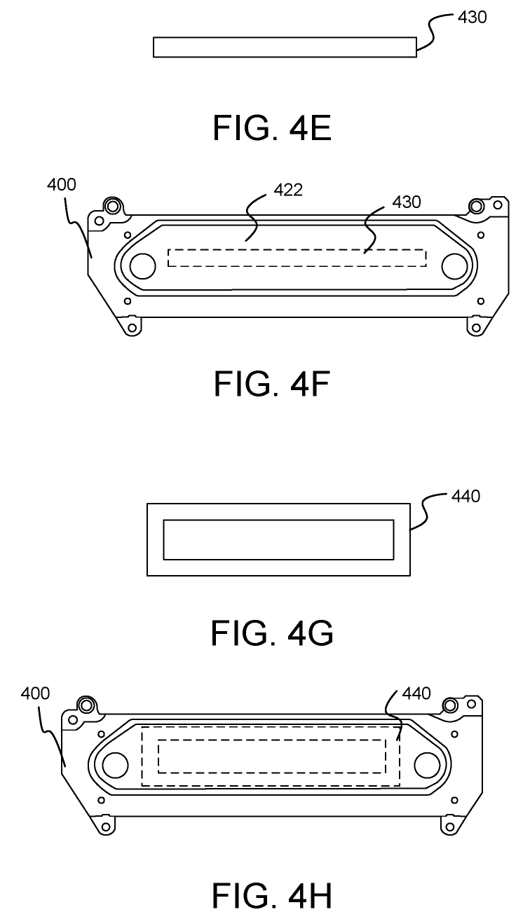

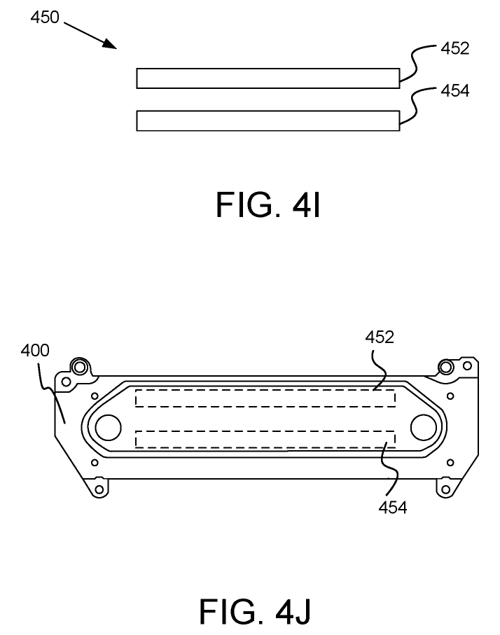

For further explanation FIGS. 4A-4J depict various geometries and installations of a reinforcement structure in a housing 400 of a cooler in accordance various embodiments of the present disclosure. FIG. 4A depicts an example reinforcement structure 410 having a geometry that conforms to a rectangular subsection of the housing 400 and includes apertures 412, 414 corresponding to the inlet port and outlet port of the housing 400. The reinforcement structure geometry of FIG. 4A is referred to a complete geometry. FIG. 4B illustrates a top view of the housing 400 having the reinforcement structure 410 embedded within the housing 400, where dashed lines indicate that reinforcement structure 410 is obscured from view.

FIG. 4C depicts an example reinforcement structure 410 having a plate geometry that conforms to a rectangular subsection of the recessed area 422 in the housing 400 that forms the fluid channel. The reinforcement structure geometry of FIG. 4D is referred to a partial geometry. FIG. 4D illustrates a top view of the housing 400 having the reinforcement structure 420 embedded within the housing 400, where dashed lines indicate that reinforcement structure 420 is obscured from view.

FIG. 4E depicts an example reinforcement structure 430 having a beam geometry. FIG. 4F illustrates a top view of the housing 400 having the reinforcement structure 430 embedded within the housing 400, where dashed lines indicate that reinforcement structure 430 is obscured from view.

FIG. 4G depicts an example reinforcement structure 440 having a ring or frame geometry having an aperture in the interior portion of the reinforcement structure 340, and it thus referred to as a ring geometry. FIG. 4H illustrates a top view of the housing 400 having the reinforcement structure 440 embedded within the housing 400, where dashed lines indicate that reinforcement structure 440 is obscured from view.

FIG. 4I depicts an example reinforcement structure 450 having two or more beam portions 452, 454, and it thus referred to as a split geometry. FIG. 4J illustrates a top view of the housing 400 having the reinforcement structure 450 embedded within the housing 400, where dashed lines indicate that reinforcement structure 450 is obscured from view.

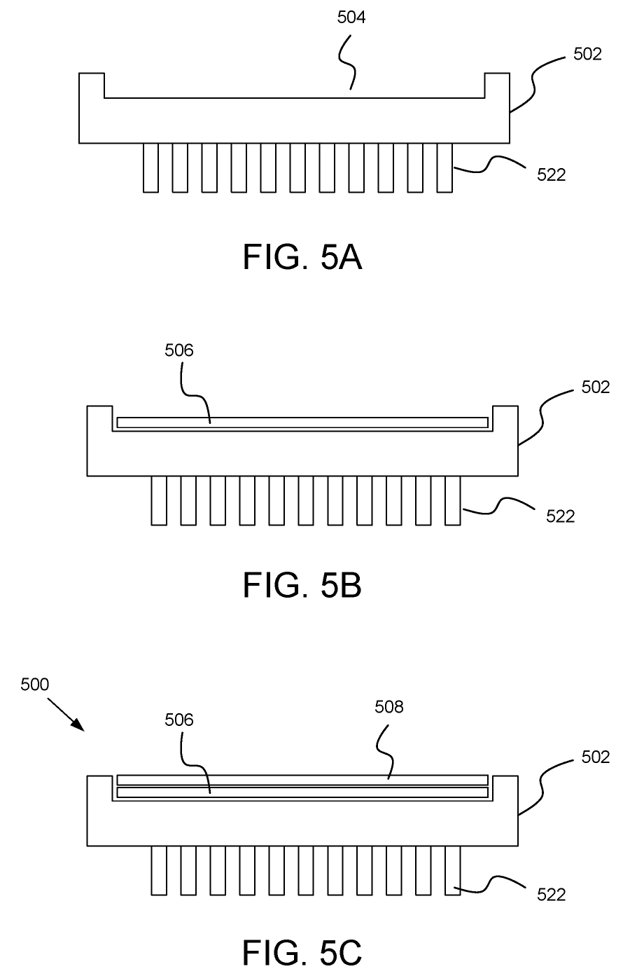

For further explanation, FIGS. 5A-5C set forth an example process for fabricating a top plate of a cooler having an embedded reinforcement structure in accordance with at least one embodiment of the present disclosure. FIG. 5A is a sectional view in which a top plate base 502 is provided having a recessed area 504 in a top surface of the top plate base 502. In some examples, fins 522 are provided on a bottom surface of the top plate base. In various examples, the top plate base 502 can be fabricated by die casting, extruding, milling, stamping, and combinations thereof. In some examples, the top plate base 502 is fabricated using aluminum. In FIG. 5B, a reinforcement structure 506 is disposed within the recessed area 504. In various examples, the reinforcement structure 506 can have the some or all of the characteristics and properties as the reinforcement structure 205 in FIGS. 2A-2C and/or any of the reinforcement structure geometries set forth in FIGS. 3A-3J. In FIG. 5C, a top plate cover 508 is disposed in the recessed area 504 over the reinforcement structure 506. In some implementations, the top plate cover 508 includes or composed entirely of aluminum. In some implementations, the top plate cover 508 includes or is composed entirely of copper. In some implementations, the top plate cover 508 includes nickel-plated copper. In some examples, a top surface of the top plate cover 508 is substantially coplanar with a top surface of the top plate base 502 outside of the recessed area 504. The top plate cover 508 is joined to the top plate base 502 to form a top plate 500 for a cooler. In some examples, the top plate cover 508 is joined to the top plate base 502 via FSW. In some examples, the top plate base 502 is fabricated using aluminum.

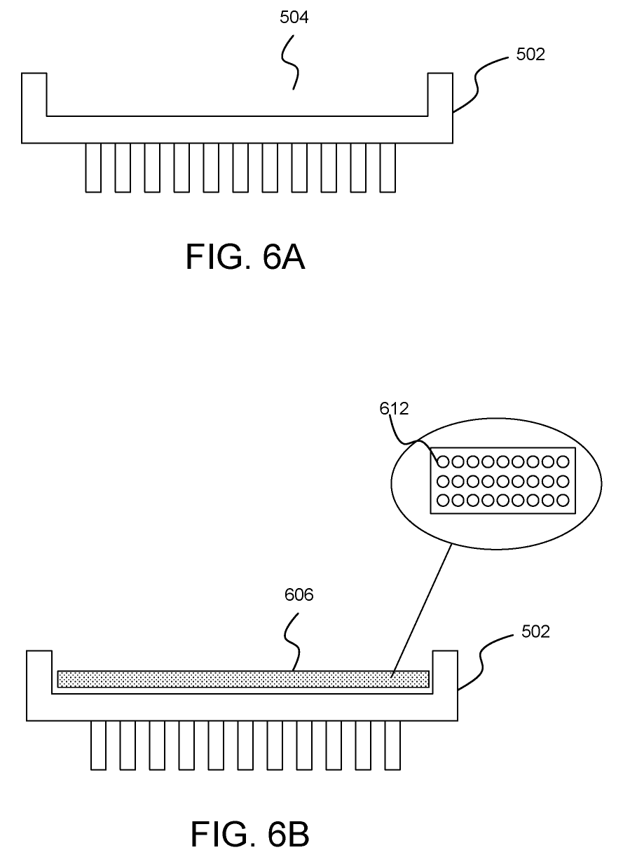

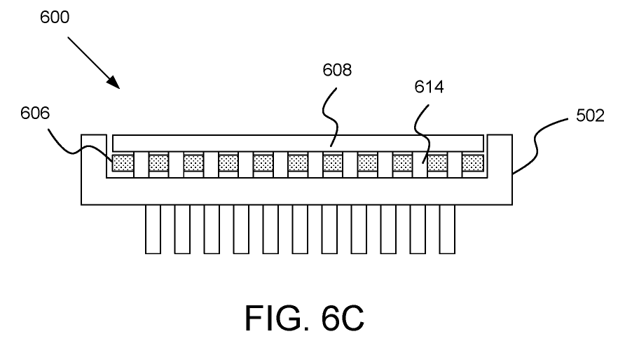

For further explanation, FIGS. 6A-6C set forth an example process for fabricating a top plate of a cooler having an embedded reinforcement structure in accordance with at least one embodiment of the present disclosure. Like FIG. 5A, FIG. 6A shows that the top plate base 502 is provided. In FIG. 6B, a reinforcement structure 606 is disposed within the recessed area 504. The reinforcement structure 606 includes a plate geometry having an array of apertures 612 formed in the reinforcement structure 606, as shown in the detail depicting a plan view of the reinforcement structure 606. In various examples, the reinforcement structure 606 can have the some or all of the characteristics and properties as the reinforcement structure 205 in FIGS. 2A-2C. In FIG. 6C, a top plate cover 608 is disposed in the recessed area 504 over the reinforcement structure 606. As shown in FIG. 6C, the top plate cover 608 includes an array of teeth 614 that correspond to the apertures 612 and engage the apertures when the top plate cover 608 is placed on the reinforcement structure 606. In some implementations, the top plate cover 608 includes or composed entirely of aluminum. In some implementations, the top plate cover 608 includes or is composed entirely of copper. In some implementations, the top plate cover 608 includes nickel-plated copper. In some examples, a top surface of the top plate cover 608 is substantially coplanar with a top surface of the top plate base 502 outside of the recessed area 504. The top plate cover 608 is joined to the top plate base 502 to form a top plate 600 for a cooler. In some examples, the top plate cover 608 is joined to the top plate base 502 via FSW.

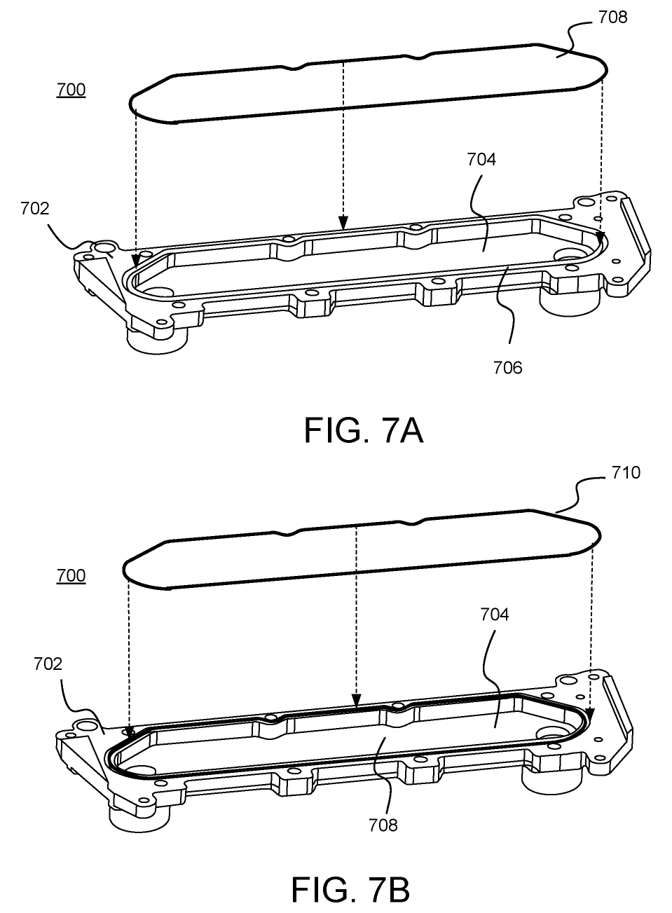

For further explanation, FIGS. 7A-7B set forth an example process for fabricating a housing of a cooler having an embedded reinforcement structure in accordance with at least one embodiment of the present disclosure. In FIG. 7A, a housing 702 for a cooler is provided, the housing 702 having a top surface that includes a recessed area 704 that forms, in part, a fluid channel of a cooler. The top surface of the housing 702 also includes a groove 706 extending along a perimeter of the housing 702 outside of the recessed area 704. In various examples, the housing 702 can be fabricated by die casting, extruding, milling, stamping, and combinations thereof. A reinforcement structure 708 is inserted into and embedded within the groove 706. The reinforcement structure 708 has a ring geometry conforming to the profile of the groove 706. In various examples, the reinforcement structure 708 can have the some or all of the characteristics and properties as the reinforcement structure 206 in FIGS. 2A-2C. Turning to FIG. 7B, a seal 710 is disposed over the reinforcement structure 708 within the groove 706. In various examples, the seal 710 can have the some or all of the characteristics and properties as the seal discussed above. In some examples, the seal 710 is a pre-formed compressible gasket composed of an elastomer (e.g., silicone or nitrile rubber), a fluoropolymer, or other deformable material. In other examples, the seal 710 is a form-in-place gasket composed of a liquid material (e.g., liquid silicone) that is deposited and cures within the groove 706. The housing 702 including the reinforcement structure 708 and seal 710 for a housing assembly 700 for a cooler.

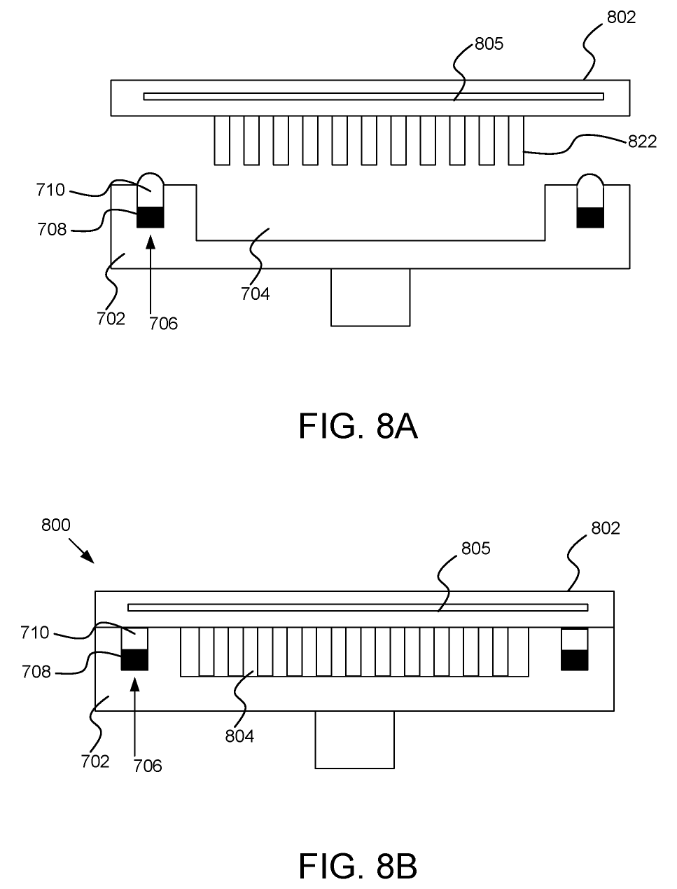

For further explanation, FIGS. 8A and 8B set forth an example process for fabricating a cooler 800 using the housing assembly of FIG. 7B. FIG. 8A is a sectional side view of a top plate 802 and the housing assembly 700 of FIG. 7B, in which the top plate 802 is disposed on the housing assembly 700. The housing assembly 700 includes the groove 706 and, disposed within the groove 706, the reinforcement structure 708 and the seal 710. In some implementation, the top plate 802 includes fins 822 that are received in the recessed area 704. In FIG. 8B, the top plate 802 is joined to the housing assembly 700, whereby the seal 710 is compressed to form a water-tight fluid channel 804. In some implementations, the top plate 802 and the housing assembly 700 are joined via FSW. In some implementations, as shown in FIGS. 8A and 8B, the top plate 802 includes a reinforcement structure 805.

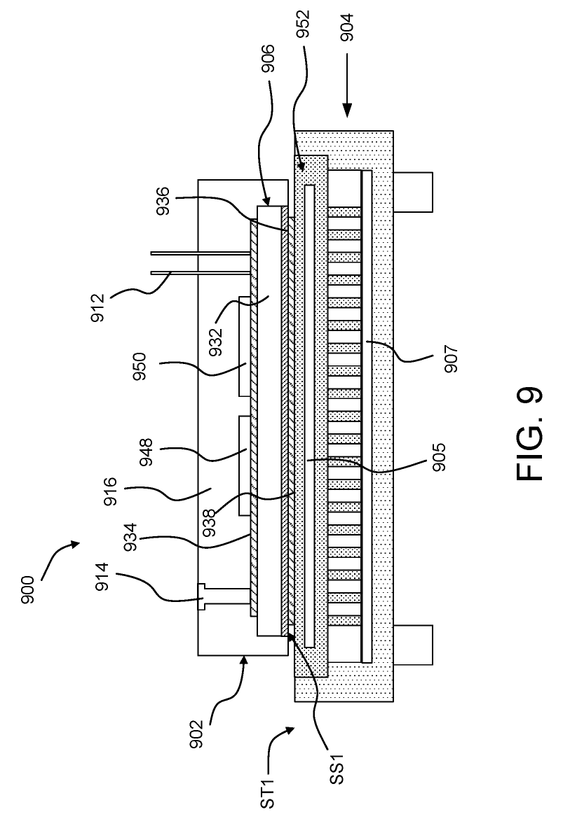

For further explanation, FIG. 9 sets forth a sectional view of another example cooling assembly 900. The example of FIG. 9 includes an example semiconductor package 902 mounted on a cooler 904. The semiconductor package 902 can be used to implement the semiconductor device 230 of FIGS. 2A-2C. In some implementations, the cooler 904 can be implemented by the cooler 210 of FIGS. 2A-2C. Particularly, the example cooling assembly 900 of FIG. 9 includes a reinforcement structure 905 disposed in a top plate 952 of the cooler 904. The example cooling assembly 900 of FIG. 9 includes a reinforcement structure 907 disposed in a housing of the cooler 904

In the example of FIG. 9, the semiconductor package 902 includes one or more semiconductor dies 948, 950. In some implementations, a semiconductor die 948, 950 can include a power device for conditioning, converting, or switching a power supply. In various examples, the semiconductor die 948, 950 can implement an IGBT power electronics device, a MOSFET power electronics device, or other electronics devices suitable for controlled switching in high voltage applications. In a particular example, the semiconductor die 948, 950 is configured as a switching device for a high voltage DC input power supply (e.g., at least 1000 V). In various examples, the semiconductor die 948, 950 can be fabricated using silicon, silicon carbide, gallium nitride, gallium arsenide, a silicon-silicon carbide hybrid material, and other suitable semiconductor die materials that will be recognized based on the present disclosure.

At least one semiconductor die 948 is mounted on a substrate 906. For example, the semiconductor dies 948 can be coupled to substrate by a thermally conductive adhesive such as solder, thermal interface material, phase change material, sinter material, and so forth. In some implementations, the substrate 906 is a DBM substrate. In some implementations, the DBM substrate (e.g., direct bonded copper (DBC)) includes an insulating layer 932 disposed between a first metal layer 934 (e.g., a top metal layer) and a second metal layer 936 (e.g., a bottom metal layer). The insulating layer 932 can be, for example, a ceramic layer. In some implementations, the insulating layer 932 can be or can include, for example, a ceramic material such as alumina (Al₂O₃) or aluminum nitride (AlN)). In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process (e.g., diffusion bonding).

In some implementations, the first metal layer 934 of the DBM substrate 906 can be or can include a patterned metal layer including one or more electrically conductive traces. In some implementations, the first metal layer 934 can be or can include a patterned layer configured to form one or more electrical circuits, one or more conductive blind and/or through vias, and/or so forth. In some examples, the first metal layer 934 includes one or more circuit portions, contacts, pads, and so forth.

In the example of FIG. 9, a bottom surface of the bottom metal layer 936 of the substrate 906 corresponds to a surface SS1 of the substrate 906 that is coupled to the cooler 904 via a thermally conductive adhesive material 938 via a bonding process such as, for example, soldering or sintering. In these implementations, the conductive adhesive material 938 can be a solder material, a sintering material (e.g., silver or copper), an epoxy material (e.g., silver filled epoxy), a thermal interface material, and so forth.

In some implementations, as shown in FIG. 9, the semiconductor package 902 includes one or more signal pins 912 extending in a direction orthogonal to the patterned first metal layer 934 on top surface of the substrate 906. In some examples, the signal pins 912 can be inserted (e.g., press-fit) into the substrate 906. For example, the signal pins 912 can be press-fit into plated openings in the substrate 906, where the plated openings can be electrically connected with respective portions of the patterned first metal layer 934 of the substrate 906. The signal pins 912 provide an external electrical interconnect for the semiconductor package 902.

In some implementations, the semiconductor package 902 includes one or more input power terminals 914 provide an external electrical interconnect for the semiconductor package 902 to receive an input power supply, such as a DC power supply. For example, the input power terminals may be located on a top surface of the semiconductor package 902. In these implementations, the semiconductor package 902 also includes one or more output power terminals (not shown) extending from the semiconductor package 902, for example, in a direction parallel to the substrate 906. For example, the power terminals 914 provide an electrical connection for power output from the semiconductor package 902. In such implementations, the semiconductor package 902 can provide power regulation, switching, phase inversion, and other power control or conditioning functions.

In some implementations, the semiconductor package assembly includes a second semiconductor die 950 mounted on the substrate 906. The semiconductor die 948 and the semiconductor die 950 are power switching devices arranged as a half bridge circuit providing high side switching and low side switching.

The semiconductor package 902 also includes molding material 916 encapsulating or partially encapsulating the components of the semiconductor package 902. For example, as shown in FIG. 9, the molding material 916 encapsulates the semiconductor die 948 and metal layer 934 of the substrate 906, while the molding material 916 partially encapsulates the substrate 906, the signal pins 912, and the power terminals 914. The bottom metal layer 936 (surface SS1) of the substrate 906 is exposed through the molding material 916, while the signal pins 912 extend through the molding material 916. The molding material 916 can be an epoxy molding compound, a resin molding compound, a gel molding compound, and so on. Though not specifically shown in FIG. 9, in some implementations, other elements can be included in the semiconductor package 902.

In some implementations, the semiconductor package 902 is bonded to the cooler 904, where the bottom metal layer 936 is bonded to a surface of the cooler 904. In some implementations, the bottom metal layer 936 and the cooler 904 are bonded using a thermal conductive adhesive material 938. In these implementations, such a conductive adhesive material can be a solder material, a sintering material (e.g., silver or copper), an epoxy material (e.g., silver filled epoxy), or a plating material (e.g., a tin plating material). In some implementations, the semiconductor package 902 is mechanically coupled to the cooler 904. For example, the semiconductor package 902 can be coupled to the cooler 904 via mechanical fasteners such as screws, clamps, nut-and-bolts, and the like. In some implementations, the semiconductor package 902 is both bonded and mechanically fastened to the cooler. For example, the semiconductor package can be sintered to the cooler 904 and screwed or clamped to the cooler 904.

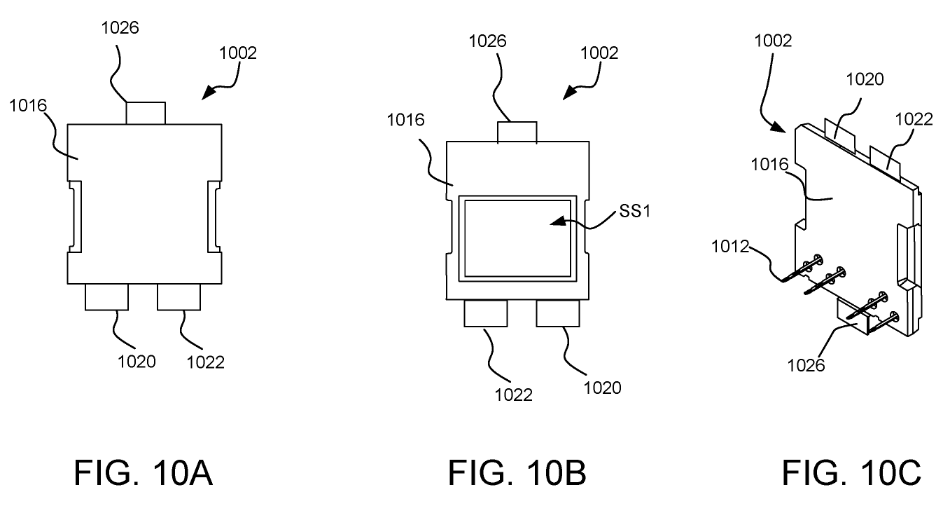

For further illustration, FIGS. 10A to 10C illustrate an external view of an example power module that can implement the semiconductor device 230 of FIGS. 2A-2C and/or the semiconductor package 902 of FIG. 9. In some examples, the power module is a power module that includes a power electronics die such as, for example, an IGBT device die or a MOSFET device die. FIG. 10A is a front view of the power module showing a top surface of molding material 1016 as well as input power terminals 1020, 1022 and an output power terminal 1026. For example, the input power terminals 1020, 1022 can correspond to the input power terminal 914 of FIG. 9. FIG. 10B is a rear view of the power module showing an exposed surface SS1 of an embedded substrate. For example, the surface SS1 can be a bottom surface of the bottom metal layer 936 of substrate 906 in FIG. 9. FIG. 10C is a perspective view of the power module showing signal pins 1012 protruding through the molding material 1016. For example, the signal pins 1012 can correspond to the signal pins 912 of FIG. 9.

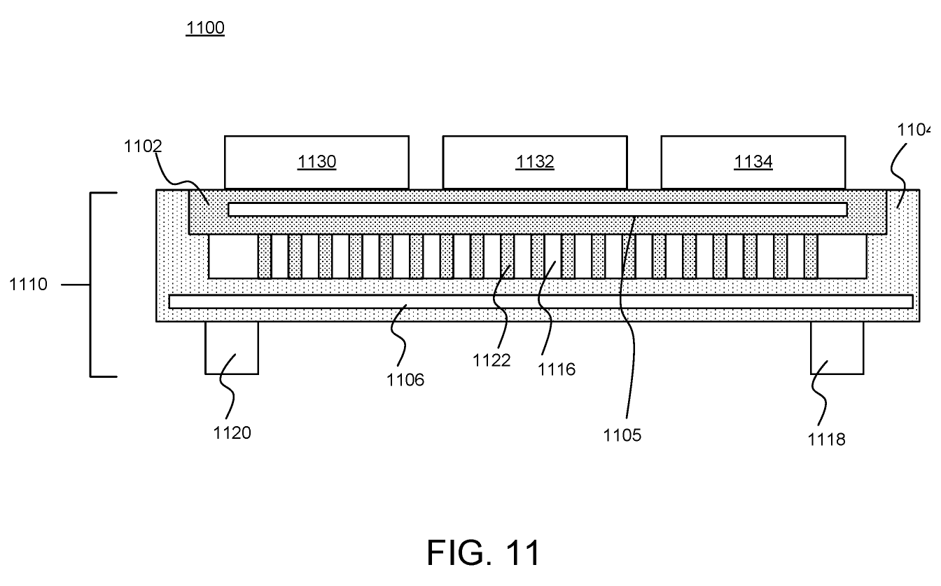

For further illustration, FIG. 11 is sectional view of an example power module cooling assembly 1100 that includes power modules 1130, 1132, 1134 coupled to a cooler 1110. Like the cooler 210 of FIG. 2B, the cooler 1110 of FIG. 11 includes a housing 1104 and a top plate 1102 that together define an internal fluid channel 1116. A fluid inlet port 1118 and a fluid outlet port 1120 are fluidly coupled to the fluid channel 1116 such that a cooling medium enters the cooler 1110 through the inlet port 1118, passes through the fluid channel 1116, and exits through the outlet port 1120. In some implementations, fins 1122 are disposed in the fluid channel 1116. In some examples, the power modules 1130, 1132, 1134 can implement the power module 1002 of FIG. 10A.

In the example of FIG. 11, the reinforcement structure 1106 is embedded in the housing 1104. In one example, the reinforcement structure 1106 can be inserted into a recess or grove defined in a wall of the housing prior to installing the top plate 1102 on the housing 1104. In another example, the reinforcement structure can be inserted into a groove or recess in the base of the housing inside the fluid channel prior to installing the top plate 1102 on the housing 1104. In such examples, the reinforcement structure 1106 may form, in part, a surface of the fluid channel. The material of the reinforcement structure 1106 is different from the material of the housing 1104. In some implementations, the reinforcement structure 1106 has a greater rigidity than the housing 1104. In some examples, the material of the reinforcement structure 1106 has a greater elastic modulus than the material of the housing 1104 at a given operational temperature. In some examples, the material of the reinforcement structure 1106 has a lower CTE than the material of the housing 1104.

In a particular example, the material of the housing 1104 is aluminum or copper-clad aluminum. In some examples, the material of the reinforcement structure 1106 is a metal or metal alloy such as stainless steel or copper. In some examples, the material of the reinforcement structure 1106 is a metal matrix composite such as aluminum silicon carbide (AlSiC). In some examples, the material of the reinforcement structure 1106 is a composite laminate such copper-clad molybdenum or copper-clad invar. In some examples, the material of the reinforcement structure 1106 is a high-modulus ceramic such as aluminum nitride (AlN) or silicon nitride (Si₃N₄). In some examples, the material of the reinforcement structure 1106 is a temperature-resistant polymer or including polymers reinforced with glass or carbon fibers.

In the example of FIG. 11, the reinforcement structure 1105 is embedded in the top plate 1102. In one example, the reinforcement structure 1105 can be inserted into the top plate 1102 during fabrication of the top plate. In another example, the reinforcement structure can be inserted into a groove or recess in the top plate 1102 prior to installing the top plate 1102 on the housing 1104. The material of the reinforcement structure 1105 is different from the material of the top plate 1102. In some implementations, the reinforcement structure 1105 has a greater rigidity than the top plate 1102. In some examples, the material of the reinforcement structure 1105 has a greater elastic modulus than the material of the top plate 1102 at a given operational temperature. In some examples, the material of the reinforcement structure 1105 has a lower CTE than the material of the top plate 1102.

In a particular example, the material of the top plate 1102 is aluminum, copper, or a hybrid construction of aluminum. For example, the top plate can have a lower portion constructed of aluminum and an upper portion constructed of copper, where the reinforcement structure 1105 is disposed between the two. In another example, the material of the top plate 1102 can be nickel-plated copper. In some examples, the material of the reinforcement structure 1105 is a metal or metal alloy such as stainless steel or copper. In some examples, the material of the reinforcement structure 1105 is a metal matrix composite such as aluminum silicon carbide (AlSiC). In some examples, the material of the reinforcement structure 1105 is a composite laminate such copper-clad molybdenum or copper-clad invar. In some examples, the material of the reinforcement structure 1105 is a high-modulus ceramic such as aluminum nitride (AlN) or silicon nitride (Si₃N₄). In some examples, the material of the reinforcement structure 1105 is a temperature-resistant polymer or including polymers reinforced with glass or carbon fibers.

It will be appreciated that, in some implementations, the reinforcement structure 1106 can be included in the housing 1104 while the reinforcement structure 1105 is omitted from the top plate 1102. It will be further appreciated that, in some implementations, the reinforcement structure 1105 can be included in the housing 1104 while reinforcement structure 1106 is omitted from the housing 1104.

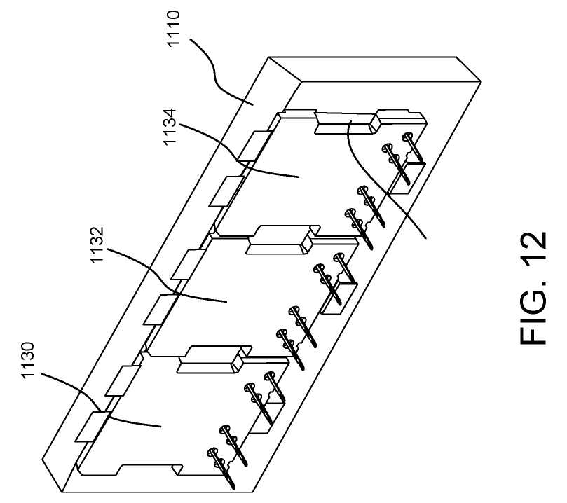

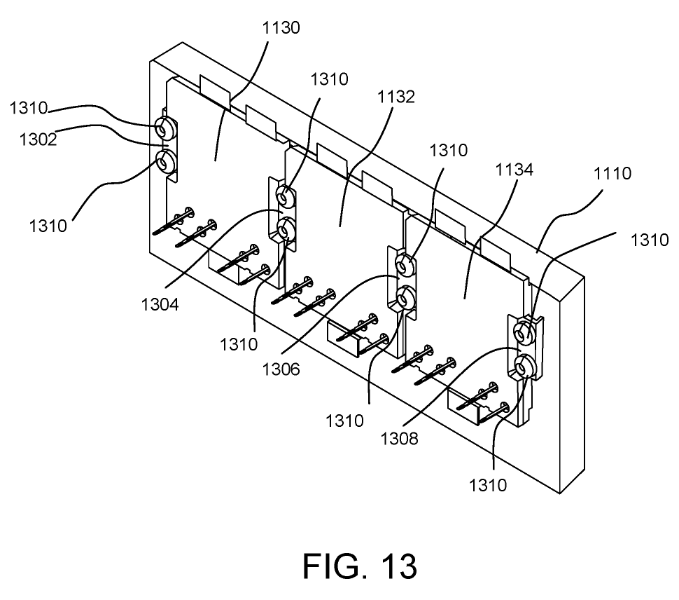

The power modules 1130, 1132, 1134 can be coupled to the cooler via bonding, attachment via mechanical fasteners, or both. FIG. 12 is a perspective view of the power module cooling assembly 1100 of FIG. 11 where the power modules 1130, 1132, 1134 are bonded to the cooler 1110 via a thermally conductive adhesive. For example, the power modules 1130, 1132, 1134 can be coupled to the cooler 1110 via a solder process or sintering process. FIG. 13 is a perspective view of the power module cooling assembly 1100 of FIG. 11 where the power modules 1130, 1132, 1134 are coupled to the cooler 1110 via mechanical fasteners. In an implementation shown in FIG. 13, washers 1302, 1304, 1306, 1308 and screws 1310 can be used to clamp the power modules 1130, 1132, 1134 to the cooler 1110. For example, each washer 1302, 1304, 1306, 1308 can include one or more through holes (not visible in the view) into which a screw 1310 is inserted. The screw 1310 passes through the through hole of the washer and fastens into a threaded hole (not visible in the view) in the surface of the top plate 1102. The washers 1302, 1304, 1306, 1308 can seated in recesses of the power modules 1130, 1132, 1134 and exert a compressive force on the power modules 1130, 1132, 1134 via mechanical coupling of the screws 1310 to the cooler 1110. It will be appreciated that other types of mechanical fastener can be employed. In some implementations, the power modules 1130, 1132, 1134 are both bonded (e.g., sintered) and mechanically fastened (e.g., screwed) to the cooler 1110.

The reinforcement structures can be integrated into one or more major components of the cooler assembly, including being integrated exclusively into the top plate, exclusively into the housing, or integrated into both the top plate and the housing. This flexible approach ensures that the cooler's rigidity is optimized for any specific application, geometry, and material requirement.

In some implementations, the power modules 1130, 1132, 1134 of FIGS. 11, 12, or 13 form a three-phase inverter with each power module 1130, 1132, 1134 providing a phase of a three-phase output. To generate the three-phase output, each phase can be driven by a half-bridge circuit comprising at least two power switching devices in each power module 1130, 1132, 1134, with each phase utilizing a high-side and a low-side switch to produce the corresponding phase voltage.

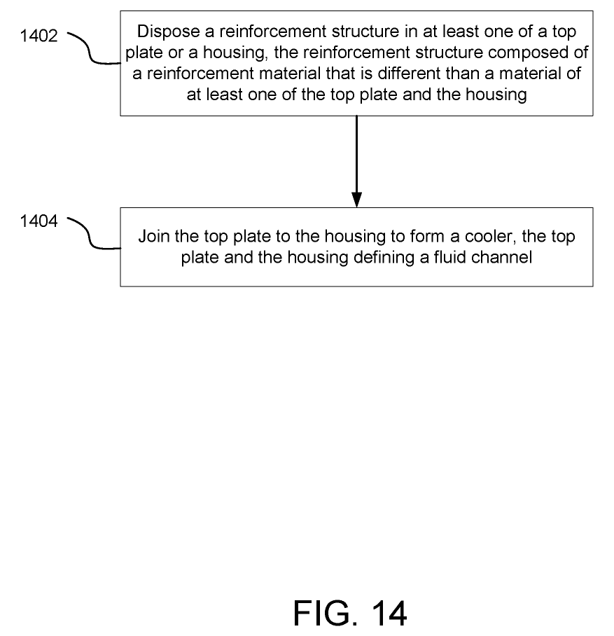

For further explanation, FIG. 14 sets forth a flow chart of an example method of fabricating a cooler in accordance with at least one embodiment of the present disclosure. The example method includes, at block 1402, disposing a reinforcement structure in at least one of a top plate and a housing. In some implementations, disposing a reinforcement structure in at least one of a top plate and a housing includes disposing a reinforcement structure in a top plate of the cooler, for example, as shown in FIGS. 2A-2C, FIGS. 5A-5C, 6A-6C, and/or FIG. 11. In some implementations, disposing a reinforcement structure in at least one of a top plate and a housing includes disposing a reinforcement structure in a housing of the cooler, for example, as shown in FIGS. 2A-2C, FIGS. 7A-7B, 8A-8B, and/or FIG. 11. In some implementations, disposing a reinforcement structure in at least one of a top plate and a housing includes disposing a first reinforcement structure in a housing of the cooler and disposing a second reinforcement structure in a top plate of the cooler. The reinforcement structure is composed of a different material than the top plate or the housing, as discussed above. The reinforcement structure increases the rigidity of the cooler, as discussed above.

The method FIG. 14 also includes, at block 1404, joining the top plate to the housing to form a cooler, the top plate and the housing defining a fluid channel. In various implementations, joining the top plate to the housing to form a cooler, the top plate and the housing defining a fluid channel includes joining the top plate and the housing via FSW, laser welding, mechanical fasteners, adhesive bonding, diffusion bonding, and so on, as discussed above.

In some examples, the method can also include bonding a semiconductor device to the cooler. In some implementations, bonding the semiconductor device to the cooler includes bonding the semiconductor device to the top plate prior to joining the top plate to the housing. In some implementations, bonding the semiconductor device to the cooler include bonding the semiconductor device to the top plate after joining the top plate to the housing. In a particular implementation, the semiconductor device is bonded to the top plate of the cooler via sintering. In other implementations, the semiconductor device is bonded to the top plate of the cooler via soldering or adhesive bonding. In various implementations, the semiconductor device can include any of the semiconductor devices discussed above, including a power module. In some implementations, the semiconductor device includes a substrate and a SiC die attached to the substrate.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package. In some implementations, one or more portions of a leadframe can be coupled to a pad (e.g., a bond pad) on at least a portion of a DBM substrate.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

What is claimed is:

1. An apparatus comprising:
a cooler including:
a housing;
a top plate joined to the housing, the top plate and the housing defining a fluid channel;
a fluid input port providing a fluid path into the fluid channel; and
a fluid output port providing a fluid path out of the fluid channel; and
a reinforcement structure disposed within the cooler, the reinforcement structure composed of a reinforcement material that is different than a material of the top plate and the housing.

2. The apparatus of claim 1, wherein the reinforcement material is a ceramic.

3. The apparatus of claim 1, wherein the reinforcement structure is embedded in the housing.

4. The apparatus of claim 3, wherein the housing includes a groove, the reinforcement structure being disposed in the groove, the housing including a seal disposed over the reinforcement structure and sealing the fluid channel.

5. The apparatus of claim 1, wherein the reinforcement structure is embedded in the top plate.

6. The apparatus of claim 5, wherein the top plate includes:
a base having a recessed area, the reinforcement structure being disposed in the recessed area; and
a cover disposed over the reinforcement structure.

7. The apparatus of claim 1, wherein the reinforcement structure is a first reinforcement structure, the apparatus including the first reinforcement structure embedded in the housing and a second reinforcement structure embedded in the top plate.

8. The apparatus of claim 1 further comprising a semiconductor device bonded to the top plate.

9. The apparatus of claim 8, wherein the semiconductor device includes a silicon carbide die.

10. An apparatus comprising:
a cooler, the cooler including a reinforcement structure disposed within the cooler, the reinforcement structure composed of a reinforcement material different than a material of the cooler; and
a power module bonded to the cooler.

11. The apparatus of claim 10, wherein the power module is a first power module, the apparatus including a second power module and a third power module bonded to the cooler.

12. The apparatus of claim 11, wherein each of the first power module, the second power module, and the third power module are configured to provide an output corresponding to a phase of a three-phase electrical output.

13. The apparatus of claim 10, wherein the power module includes a first transistor die corresponding to a high side of a half bridge circuit and a second transistor die corresponding to a low side of the half bridge circuit.

14. The apparatus of claim 10, wherein the cooler includes:
an upper portion; and
a lower portion joined to the upper portion, the upper portion and the lower portion defining a fluid channel, wherein the reinforcement structure is embedded in at least one of the upper portion and the lower portion.

15. The apparatus of claim 14, wherein the reinforcement structure is a first reinforcement structure, the apparatus including the first reinforcement structure embedded in the upper portion and a second reinforcement structure embedded in the lower portion.

16. The apparatus of claim 10, wherein the reinforcement structure is composed of a ceramic material.

17. A method comprising:
disposing a reinforcement structure in at least one of a top plate or a housing, the reinforcement structure composed of a reinforcement material that is different than a material of at least one of the top plate and the housing; and
joining the top plate to the housing to form a cooler, the top plate and the housing defining a fluid channel, the cooler including a fluid input port providing a fluid path into the fluid channel and a fluid output port providing a fluid path out of the fluid channel.

18. The method of claim 17, wherein disposing the reinforcement structure in at least one of a top plate and a housing includes embedding the reinforcement structure in the housing.

19. The method of claim 17, wherein disposing the reinforcement structure in at least one of a top plate and a housing includes embedding the reinforcement structure in the top plate.

20. The method of claim 17, wherein the reinforcement material is a ceramic and the material of at least one of the housing and the top plate is aluminum.

21. The method of claim 17, wherein joining the top plate to the housing includes friction stir welding (FSW).
